(19) United States
(12) Patent Application Publication
(10) Pub. No.: US 2008/0228415 A1
(43) Pub. Date: Sep. 18, 2008

(54) Semiconductor testing instrument to determine safe operating area

(76) Inventors: Peter Ladbrooke, Suffolk (GB); Neil Goodship, Cambridge (GB)

Correspondence Address: Silicon Valley Patent Group LLP, 18805 Cox Avenue, Suite 220, Saratoga, CA, 95070, US

(21) Appl. No.: 11/370,588

(22) Filed: Mar. 8, 2006

Related U.S. Application Data
(63) Continuation of application No. 10/529,963, now abandoned.

(30) Foreign Application Priority Data
Oct. 11, 2002 (GB) 0223632.1

(51) Int. Cl. G01R 19/00

(52) U.S. Cl. 702/65; 324/76.11

(57) ABSTRACT

An instrument for determination of the dc safe area of operation of a semiconductor device-under-test comprises a means to apply an adjustable bias at the input of a device-under-test, wherein the means comprises a dc biaser to apply a dc bias at a bias point within the safe operating limit, and a variable biaser subsequently to apply a variable bias comprising fast, superimposed rectangular bipolar pulses, and wherein the instrument further comprises means to measure the current response thereto so as to permit extrapolation of a detailed I-V response in the vicinity of the safe operating limit. A method of determination of the dc safe area of operation of a semiconductor device-under-test is also described.

### CROSS REFERENCE TO RELATED APPLICATIONS

This application is a continuation of U.S. patent application Ser. No. 10/529,963 deposited with the U.S. Patent Office Mar. 31, 2005 and now pending, which is a U.S. National Stage application of PCT/GB2003/004473 filed Oct. 13, 2003, which claims the benefit of Great Britain Patent Application No. 0223632.1 filed Oct. 11, 2002. Priority to each of these applications is hereby claimed, and the entirety of each of these applications is incorporated herein by reference.

### BACKGROUND

The present invention relates to a semiconductor testing instrument, and in particular to an instrument for determining the safe area of operation of such a device, especially of the bipolar type, and especially at RF frequencies and/or under large signal conditions. The invention also relates to a method of such measurement.

Increasingly, modern electronic systems rely upon semiconductor devices operated under large-signal conditions. For example, mobile phone handsets, power amplifiers, base stations, radars, missile guidance systems, electronic instruments, and other like electronic systems use semiconductor integrated circuits (ICs) or discrete devices which are designed to operate under such large signal conditions.

For semiconductor devices of all types, including transistor devices, semiconductor LEDs and lasers and other semiconductor devices, there is a thus a general requirement to be able to determine the dc safe area of operation (SOA), in the high-voltage low-current limit, without risking destruction of the device-under-test, and thus to identify the safe area of operation for the device.

This applies to most types of transistor devices (discrete or integrated) including, without limitation, those listed below, but is particularly the case for bipolar and like devices which are prone to undergo catastrophic avalanche breakdown outside the operational area.
bipolar transistors: NPN and PNP devices. [1]
silicon FETs including MOSFETs (metal-oxide-semiconductor field-effect transistors) and LDMOS (laterally diffused metal oxide semiconductor). [1]
MESFETs (metal-electrode-semiconductor field-effect transistors. Most commonly GaAsFETs when fabricated in GaAs). [2]
HEMTs (high electron mobility transistors). [2]
HBTs (heterojunction bipolar transistors). [1,2]

Note that devices marked [1] are generally fabricated in silicon (Si), silicon-germanium (SiGe) or silicon carbide (SiC), whereas devices marked [2] are generally fabricated using high-electron mobility compound semiconductor materials such as gallium arsenide (GaAs) or indium phosphide (InP).

### SUMMARY

One aspect of the present invention can mitigate some or all of the above disadvantages.

Another aspect of several embodiments of the present invention is to provide a testing instrument and method for accurate determination of the dc safe area of operation (SOA), in the high-voltage low-current limit, without risking destruction of the device-under-test, and thus to identify the safe area of operation for the device-under-test.

In accordance with the invention at its broadest an instrument for determination of the dc safe area of operation of a semiconductor device-under-test comprises a first dc biaser to apply an adjustable dc bias at a first channel and in particular at the input of a device-under-test, and a means to apply a bias signal at a second channel and in particular at the output of a device-under-test which means comprises a second dc biaser to apply a dc bias at a bias point within the safe operating limit, and a variable or pulse biaser subsequently to apply a variable or pulse bias signal comprising fast, superimposed rectangular bipolar pulses, and wherein the instrument further comprises means to measure the current response thereto so as to permit extrapolation of a detailed I-V response in the vicinity of the safe operating limit.

In accordance with the principles of the invention a dc bias is applied by the instrument within the safe operating limit of the device-under-test in conventional manner. A variable or pulse bias signal comprising fast, rectangular bipolar pulses is then applied by the instrument superimposed on the dc signal with the intention of taking the device-under-test beyond the operational limit.

This takes the device-under-test for a short period beyond the safe operating limit, and in its particular preferred application with bipolar and like devices, into the avalanche breakdown area. However, it is a characteristic feature of the instrument in accordance with the invention that the fast effective pulse rates, combined with rapid measurement times, enable this breakdown area to be identified before catastrophic breakdown has time to occur in the device-under-test.

Each pulse is generally rectangular in particular in its lead profile, having a rise time very much less than effective total pulse length. As discussed below the tail profile is less critical. The dc bias and pulse amplitude can be independently variable. A pulse amplitude may be any non-zero value, positive or negative, superimposed on the dc bias to generate a bipolar signal. Preferably separately variable dc biases are applied at the two channels, for example at input and output, of the device-under-test. A pulse amplitude is superimposed at one channel, for example the output. For certain applications a further pulse amplitude, synchronous in time with the first (eg output) pulse but of separately variable pulse amplitude, may be superimposed on the dc bias at the other channel (eg input), but this is not an absolute requirement of the invention which requires the pulse at a single channel only.

Conveniently, successive pulses are applied to the dc bias with progressively increasing amplitude until the breakdown point is exceeded and the breakdown area thus identified.

For accurate determination of the breakdown point, the above process may be repeated as an iterative succession. An initial dc bias is applied at a point known to be well within the safe operating area of the device-under-test. A pulsed signal is superimposed, and in particular a pulsed signal of progressively increased amplitude is superimposed. As incipient breakdown is detected the pulsed signal is removed. A second dc biasing point is determined in the vicinity of but safely below the breakdown point as identified by the first stage in the iterative process, and the process is repeated. After several iterations a very accurately determined breakdown point is obtained.

Thus, in accordance with the foregoing, the invention permits accurate and specific measurement of the safe operating area, and in particular of any catastrophic breakdown point, of a particular semiconductor device in non-destructive manner.

It should be understood that the reference to a signal having “superimposed” dc and pulse elements is intended to be descriptive of the effective signal profile at the device only. It is not meant to imply that the dc bias and pulse elements of the overall signal are separately generated and identifiably superimposed at some stage by the apparatus. Although such a means of generating the desired signal can be convenient in many instances, the invention is not limited to such cases, but extends to all cases where the desired signal profile is applied, however generated.

In principle, I-V curves at RF or microwave frequencies could be measured using any wave form that had a fast enough rate. The problem is one of interpretation. To recover the desired characteristic I-V curves it is necessary to apply a measurement technique which gives the characteristics of the device itself, uncorrupted by and completely independent of the method or instrument used to make the measurement. In other words, we need to apply a wave form which admits of ready interpretation of the response. Accordingly, the invention uses step pulses with flat tops up to the point of sampling to give a generally square form to the pulse. This requires a rapid rise to the flat top condition. However it will be appreciated that it is only the lead profile of the pulse that needs this generally square form, since the degradation on the tail side occurs after sampling and is not material to the device response.

Preferably, the pulsed wave form is essentially critically damped so as to achieve a minimum rise time up to the point where the pulses become substantially flat. However it is primarily the lead profile of the pulse that needs this generally square form, with degradation on the tail side being less critical to the device response provided overall pulse length is not so long as to initiate breakdown.

The particular problem encountered at the high pulse frequencies required by the instrument of invention is that of applying a suitable biasing pulse, maintaining the pulse shape and integrity, and rapidly measuring current responses, whilst at the same time achieving device stability. At these frequencies, practical devices tend to undergo spurious oscillation when under test.

It has been suggested in the prior art that higher frequency pulses could be applied while keeping devices stable by use of a “bias tee.” However, the capacitances within such a bias tee give the bias tee itself its own frequency response, which in practice limits the speed of the pulse which can be used. By contrast, in the present invention, fast stepped pulses in particular with pulse lengths below about one μs and more preferably in some cases below 100 nanoseconds, are desired if avalanche effects are to be avoided.

In a particular embodiment of the invention, this is achieved in that the means to apply the adjustable bias at the input comprises a high stability voltage source serially connected to the input via a resistor, and preferably further serially connected through a low pass filter.

The power supply is selected to have a very low output impedance even at the high frequencies used to apply the test pulse.

The effect of this arrangement as incipient spurious oscillations arise will be understood. To spurious oscillation disturbances the near perfect power supply appears as a short. The circuit therefore functions in effect as a resistive termination, and it is well understood that such a resistive termination is effective as a means of unconditionally stabilising a transistor or like device.

The resistor used to achieve this resistive termination must be very low in parasitic reactances. Device stabilisation is preferably achieved by a resistance in the range of some 10 s of Ω to 100 s of Ω, for example 50Ω to 1000Ω.

The inclusion of an optional low pass filter represents a second stabilisation measure which increases the effectiveness of stabilisation at input. The low pass filter is selected such as to be effectively transparent at the pulse rates and rise times under test, but act to inhibit time dependent variations in current or voltage at higher oscillation frequencies.

Conveniently, the resistance is followed by a series inductor and a shunt capacitor to form the low pass filter.

Sample measuring points are provided across the resistor. In particular, current and/or voltage measuring means are provided to measure input and response currents and voltages at high speed, preferably within 5 ns, and in particular within 1-2 ns. Input and output pulse generators are preferably in the form of operational amplifiers having output impedances kept low preferably no more than a few Ω, for example less than 5Ω, and in particular below 1Ω, even at RF and microwave frequencies. This enables short pulses to be generated, preferably below 100 ns, and for example down to a few tens of ns.

However, although pulse lengths down below 1 μs, and in particular down to the order of 100 ns, are desirable in any event, it will be apparent to the skilled person that as indicated above a key parameter is also the speed of measurement. If measurement can be effected as quickly as the order of a few 10 ns, and more preferably still of the order of a few ns, from the beginning of the pulse then the effective pulse length as far as the device is concerned is reduced accordingly. The extent to which such a rapid measurement can be taken depends critically upon the profile of the leading or rising edge of the square wave. Once the measurement is taken it actually becomes entirely academic how the wave form decays. For practical purposes we can say that the rise time at the leading edge of the square wave needs to be one tenth or less of the effective pulse time. Where we rely on this fast sampling technique it correspondingly follows that the rise time must be less than one tenth of the time after pulse commencement where a sample is taken.

It will be appreciated that at the voltage/current levels required for many of the devices which it is envisaged to test it is impractical with current integrated circuit technology to get rise times below a few tens of ns.

However, in accordance with a preferred embodiment of the invention, a very fast effect pulse rate can be obtained by using a mechanical switch in conjunction with a short sampling period. In accordance with the invention, the means to supply a variable bias for superposition onto the fixed bias, rather than being a pulse generator to generate the desired wave form, comprises two separate dc supplies, each with separately variable amplitude, the first supplying the base dc bias in accordance with the principles of the invention and the second the fast pulse to voltage, and a means to selectively apply and disapply this second dc supply so as to produce an effective square-wave pulse. The second dc supply may be applied as a superimposition on the first to generate a pulse, or as an alternative to the first to generate a pulse, with the switch being configured accordingly.

The means to selectively apply and disapply the second dc supply is conveniently a fast switch. To obtain an effective square pulse it is desirable that rise time is very short compared with the pulse length. It will then generally be desirable that fast switching, for example with a switching time between states of down to a few tens of picoseconds, can be achieved.

Since only a simple switch is now required rather than a complex operational amplifier, very fast effective pulse generation is possible. The switch can be electronic, electromechanical or mechanical. In each case switching over a time period below about 1 ns is possible, making sampling times of the order of a few ns practical. However at the large power levels at which modern devices can be operated, such switching times are not always readily achieved electronically, and in such applications a fast electromechanical switch such as a fast relay and for example a mercury reed relay, might be preferred.

To achieve fast sampling times and thus fast effective pulse lengths, current and/or voltage measuring means are operatively coupled to the said switch so as to make a high-speed measurement within the said period of a few ns after actuation of the switch. The effective pulse length experienced by the device is thus reduced yet further to the order of a few ns.

The skilled person familiar with high-accuracy dc measurements will have an expectation that pulsed I (V) measurements should be made using four-point probe (or Kelvin type) methods. These are effective in reducing the effect of parasitic series resistances attributable to cabling and the like between measuring instrument and device-under-test which are the dominant problem at dc or low frequencies.

Parasitic series resistance, errors arising from which would be eliminated by a Kelvin four-point probe method, is far from being the most troublesome source of error in pulsed measurements. The main problems in this instance include parallel capacitance (including the capacitance of any connecting cable); and series inductance (including the inductance of any connecting cable).

To mitigate these problems, in a preferred embodiment the length of any connection between the device-under-test and the response measuring means in the measuring instrument is kept to a minimum, in that a remote head is provided including at least the response measuring means which may be connected to a primary supply and control means by remote cable, but into which the device-under-test may be directly connected. This direct connection eliminates the need for connecting cables and the like, and mitigates the problems outlined above.

For similar reasons, the remote head may comprise additionally or alternatively the means to apply the signal, or at least that a part thereof for example comprising the means to generate the superimposed fast, generally rectangular, synchronous bipolar pulses.

This last alternative is a particularly preferred feature wherein the fast pulses are generated by a fast switching arrangement as above described. In this case the effectiveness of the switching is maintained if the cable connection between the semiconductor device-under-test and the pulse generator is kept to a minimum. Accordingly, the pulse generator, and optionally also the response measuring means, are preferably provided in a remote head which may be connected to a primary supply and control means by remote cable, but into which the device-under-test may be directly connected.

In accordance with a further aspect of the invention, a method for determination of the dc safe area of operation of a semiconductor device-under-test comprises
applying a dc bias at a first channel such as the input of the device-under-test;
applying a dc bias at a second channel such as the output of the device-under-test at a bias point within the safe operating limit of the device-under-test;
applying a variable stimulus at the second channel comprising superimposed fast rectangular bipolar pulses;
rapidly measuring the current response thereto at both the channels such as at both input and output;
extrapolating from the responses a detailed I-V response for the device in the vicinity of the safe operating limit.

Preferred features of the method and preferred or necessary parameters for the bipolar pulse, pulse rates, measurement times etc will be understood by analogy with the foregoing.

In particular the method is preferably performed repeatedly as an iterative succession, for example comprising the steps of applying an initial dc bias at a point known to be well within the safe operating area of the device-under-test; superimposing a pulsed bias and in particular a pulsed bias of progressively increased amplitude; detecting incipient breakdown and removing the pulsed bias; determining a second dc biasing point nearer to but safely below the breakdown point as identified hereinbefore; repeating the process steps above until a sufficiently accurate characterisation of the breakdown point is obtained.

### BRIEF DESCRIPTION OF THE DRAWINGS

The invention will now be described by way of example only with reference to FIGS. 1 to 15 of the accompanying drawings wherein:

FIG. 1 is an illustration of the I-V characteristics for a typical bipolar device;

FIG. 2 illustrates the principle of resistively terminating a FET;

FIG. 3 illustrates an arrangement for an embodiment of the invention supplying a test signal at the gate of an FET;

FIG. 4 illustrates an effective equivalent circuit to FIG. 3 as far as spurious noise oscillations are concerned;

FIGS. 5 and 6 illustrate preferred pulse generators;

FIGS. 7 and 8 illustrate an example circuit especially suited for application of the invention to a bipolar transistor;

FIG. 9 illustrates the problem of stray shunt capacitance;

FIGS. 10 to 12 illustrate an embodiment of the invention adapted to produce particularly short pulse lengths of the order of 1 ns;

FIGS. 13 and 14 illustrate alternative arrangements by which fast effective pulses can be generated using fast switching;

FIG. 15 illustrates the value of using a remote head for at least the data measurement means, and preferably also for the input signal generation.

### DETAILED DESCRIPTION

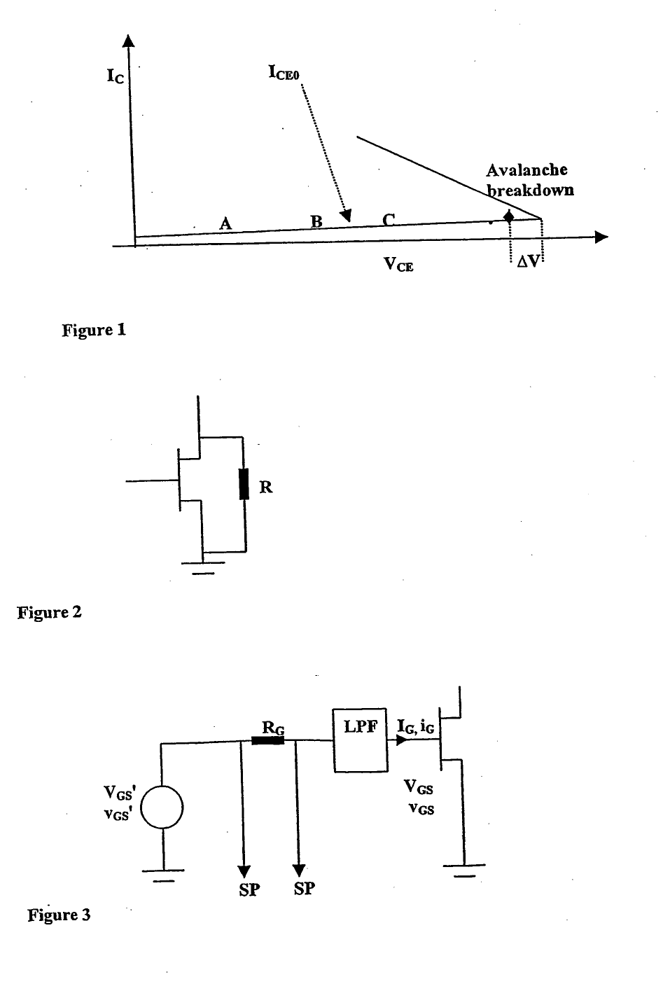

I-V characteristics for a typical bipolar semiconductor device-under-test are shown in FIG. 1. I_{CEO} is the current flowing from collector-to-emitter with the base open circuit (i_{B}=0). The I-V curve illustrates the catastrophic avalanche breakdown which is a particular characteristic of bipolar devices. Some FETs and HEMTs collapse in a similar manner. The invention is particularly applicable to the detection of the safe operating limit in devices which undergo this or another form of runaway breakdown at the edge of that limit, and is discussed by way of example in relation to a bipolar device, but is not limited to such use.

The requirement is to detect the onset of avalanche breakdown very rapidly, and then reduce the voltage so it does not occur. For this the following approach is adopted.

The device-under-test is biased under DC conditions at the point marked ♦ on the curve in FIG. 1. This is within a fraction of a volt of breakdown and the voltage difference is ΔV. This remaining voltage ΔV is then applied under pulse conditions.

The key is to keep the pulse and sampling times short enough to detect and catch the avalanche before it becomes destructive, i. e. before runaway sets in.

In this approach it is important to start conservatively. Referring to FIG. 1, the process is carried out iteratively from a series of bias points successively nearer to the breakdown point.

The process begins at test point A and then a steady increase in the pulse amplitude is applied until breakdown just starts to occur. At this point the pulse must be rapidly removed, but the breakdown voltage will now be approximately known so it is possible to increase the voltage such that test point B (TPB) is reached. Now there is a new, reduced, ΔV between this TPB voltage and breakdown and the process is repeated-setting to test point C, etc.—until the DC test point voltages converge at breakdown. Then the breakdown voltage is accurately known.

In the example this procedure is followed manually but rapidly. An automated device adapted to perform the iteration without user intervention could be envisaged.

A test device in accordance with the invention applies the DC bias and applies pulses at this bias point to the device-under-test. However, parasitic impedances arise in series with the gate (or base). Also there are parasitic impedances from these terminals to ground. These impedances arise inevitably from the device itself, from jigs supporting the device-under-test, from the measuring instrument, connecting cable, etc. The existence of these parasitic impedances means that the device-under-test is subject to a risk of oscillation.

Meaningful measurements cannot proceed with an oscillating device. The question therefore arises as to how to achieve device stability. With the device in accordance with the invention arrangements are made to precisely ensure stability. How this is achieved is discussed below.

In order to stabilise a transistor unconditionally microwave engineers may resistively terminate the output of the device-drain to ground for an FET and collector to ground for a bipolar. This principle is illustrated in FIG. 2. Although an FET transistor is shown it will be understood that the same approach is also applicable by analogy to a bipolar type device.

It is a key feature of the preferred embodiment of the present invention that the testing device is adapted to mimic this principle.

FIG. 3 illustrates how this is achieved in the example device on the input side (gate or base). In the illustrated example voltages are measured at the sampling points SP. The choice of R_{G} is critical, being some tens to hundreds of ohms and very low in parasitic reactances. A very important feature is that the introduction of the low-pass filter (LPF) represents a second stabilisation measure.

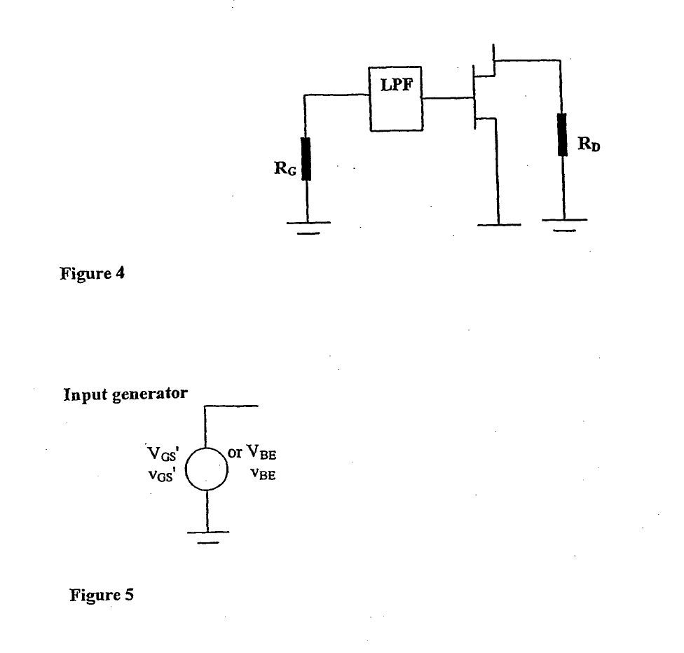

As far as spurious “incipient” oscillation or noise signals are concerned the circuit appears as shown in FIG. 4 (in which the output is also shown as resistively terminated by the resistor R_{D}).

The low-pass filter (LPF) has to be transparent at the pulse rates and rise times attendant to the measurement, but also must be such as to quench and inhibit time-dependent variations in current or voltage at higher (oscillation) frequencies.

In practice the LPF is realised as a combination of shunt capacitors and series inductors in the gate (or base) lead.

This arrangement:
Keeps the device-under-test stable.
Allows input and output conduction currents to be measured under dc and dynamic conditions.
Allows dc biases and pulses to be applied simultaneously to the device-under-test.
Allows fast (few tens of nanoseconds rise time) pulses to be applied.
Provides a measure of buffering or isolation of the device-under-test, which preserves the pulse shape and integrity.
Provides a measure of protection from device destruction by current runaway-especially with bipolar devices.
Provides a measure of short-circuit protection for the instrument.

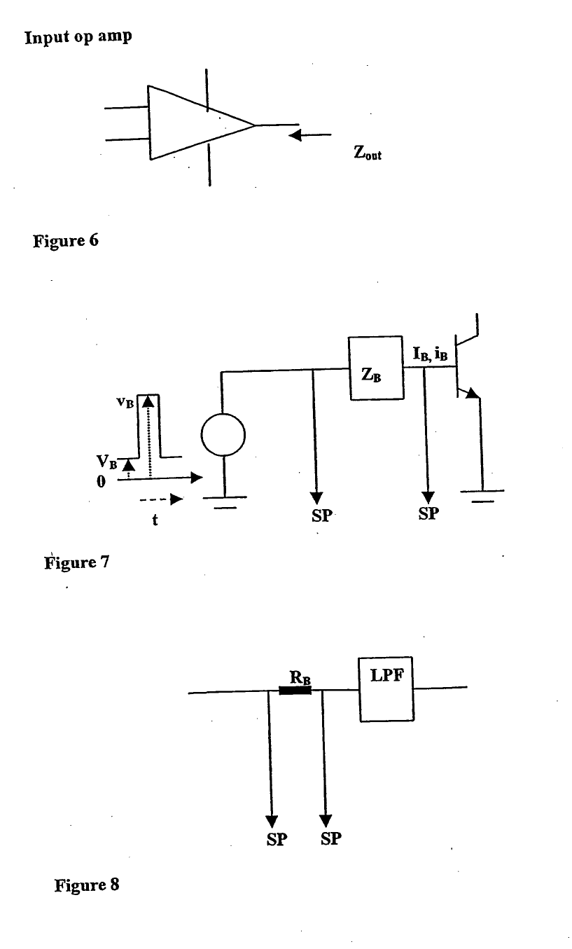

There are also important special aspects regarding the pulse generator. This is indicated in FIG. 5. This generator may be realised in practice in the form of an operational amplifier (op amp), as shown in FIG. 6.

The important requirement is that for the op amp the output impedance Zₒᵤₜ must be kept extremely low-even at RF and microwave frequencies. For this the op amp need to be specially selected.

The consequence is that this scheme allows short pulses to be generated-down to a few tens of nanoseconds (ns).

The foregoing examples have been given in terms of FET transistors allowing good illustration of the principles of resistive termination. However, the invention is particularly applicable to bipolar transistors and the like which undergo catastrophic avalanche failure. Bipolar Transistor Measurements present particular difficulties. FIGS. 7 and 8 illustrate the principles of an embodiment of the invention in measuring, at constant base current IB, the dynamic I-V characteristics of bipolar transistors-which are notoriously unstable.

There are two important issues;
(i) How to measure the dynamic I-V conduction characteristics with IB constant as parameter, whilst keeping the device stable.
(ii) Defining the measurement conditions for valid measurement of the dynamic I-V conduction characteristics uncorrupted by the reactive effects.

Considering issue (ii) first of all. The measurement conditions are satisfied by maintaining the pulse length greater than a time as defined by the following inequality:

$${t}_{pulse} \geq {t}_{ON} = \frac{( β + 1 ) {i}_{BStep}}{2 π {f}_{T} ( \frac{kT}{q} )} {R}_{B} λ n [ 1 + \frac{{v}_{BEON}}{{i}_{BSTEP} {R}_{B}} ]$$

In which: t_{ON} is the time required to fully turn the transistor on, β is the DC collector-to-base current ratio, f_{T} is the current transition frequency and all the remaining quantities are readily known. At normal ambient temperature (“room” temperature) T=298K and the kT/q ratio is 0.025V.

There is one connection approach that might ideally be desired-but which cannot be achieved-which is to drive the base input from a constant current source. Microwave and RF engineers, will understand that this cannot practicably be achieved. At the high frequencies associated with the very short pulses open or short-circuit terminations (as for example are necessary with h-parameter or y-parameter characterisation of the device-under-test) are infeasible. (Under small-signal linearized conditions one can measure S-parameters and then transform the results into h, y, z ABCD or other sets of parameters. However, under large-signal conditions this cannot be done.)

So, for measuring a bipolar transistor, what has to be established is the type of circuit indicated in FIG. 7. As before, sampling points SP are immediately followed by A>D converters within the measuring instrument.

Regarding Z_{B}; this required series impedance is: (a) realistic in the practical case, and (b) needed for device-under-test stability.

With Z_{B} it is now possible to measure directly what is required, as follows: In the illustrated example Z_{B} is realised as resistor R_{B} in series with a low-pass filter (LPF), indicated in FIG. 8.

R_{B} is typically a few hundreds of ohms in value and it must also be very low in parasitic reactances. Note that the value range is around an order-of-magnitude larger than for R_{D} described in conjunction with measurements on FETs, see above. The LPF has to be “transparent” at the pulse rates and rise times in use. In this method fast-sampling is used at the SP points. V_{B}, v_{B} are iterated (digitally) until I_{B}, i_{B} are as set-or as desired.

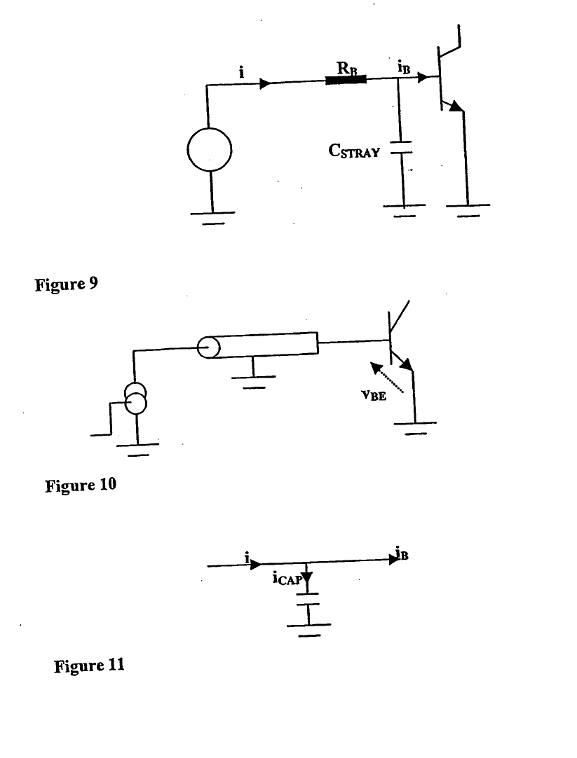

FIG. 9 illustrates an embodiment of the device specifically relevant to measurement at very low i_{B} values-in the region of 1 μA order of magnitude.

The stray instrument capacitance C_{STRAY} represents a problem and special low-capacitance buffering techniques, internal to the measuring instrument, are required to keep the effective stray capacitance low-down to the order of a few pF. As this stray capacitance is made smaller, so i_{B} can be set ever smaller-within known accuracy limits.

FIG. 10 illustrates an embodiment of the device specifically adapted for pulse lengths having an effective order of magnitude down to a few nanosecond.

A feature is exploited when the device-under-test is a bipolar transistor which makes use of stray capacitance in the connecting cable run. This enables effective pulse lengths to be generated down to the order of a few ns, by relying on the principle that the effective pulse length constitutes the time between the device-under-test turning ON and the sampling point, and that the only real limitation on reduction of this effective pulse length is the need for the sampling time to be an order of magnitude bigger than the rise time.

The effect to be exploited assumes that a connection is made using a cable run that is predominantly capacitive as illustrated in FIG. 10. This is approximately equivalent to the simple circuit shown in FIG. 11 which shows the current i_{CAP} that flows in the capacitive element of the cable.

The key aspects are:
(I) Start from V_{BE}=0 (i.e. i_{B}=0), then:
(II) Turn the pulse on-from a current generator source.

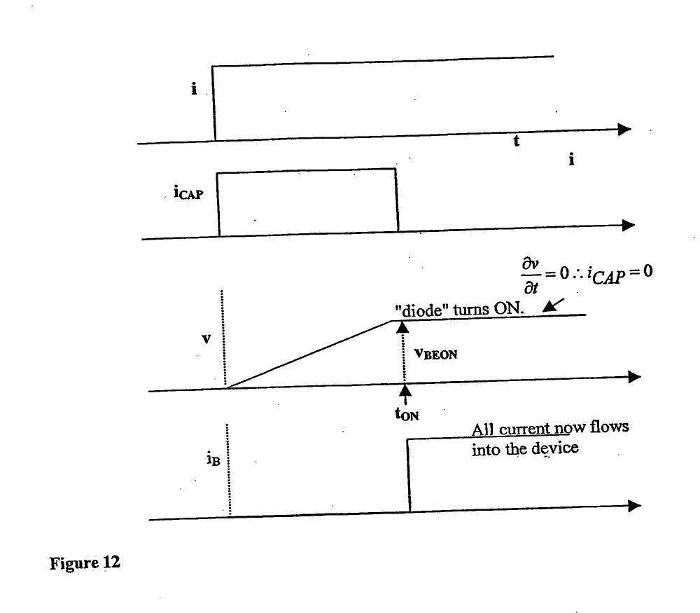

The waveforms of FIG. 12 show the effects—remembering that

$$i = C \frac{d v}{d t}$$

The time t_{ON} can be ascertained by continually sampling (since when i_{B}=0, i_{C}=0). The sample acquisition time is around 1 to 2 ns. Therefore it is possible to sample i_{C} and this enables measurements at effective pulse lengths down to as low as the order of 1 ns.

FIG. 13 shows an alternative input to generate particularly high effective pulse rates. In the previous examples, pulses were generated by combined application of a dc bias and of a pulsed wave of suitable form applied by, for example, an operational amplifier. At the large operating voltages and currents necessary to test typical modern FET and bipolar transistors and other devices for high power applications, it is unlikely to be practical with present technology to generate and transmit or deliver via cables pulse lengths below the order of one or a few hundred ns. Although the foregoing example gives a method of getting low effective pulse lengths for bipolar transistors using the stray capacity of the cable, such an effect could not be exploited for FETs.

In this example the underlying bias is applied by a first dc source (S1), and the “variable”, pulse bias is applied by a second dc source (S2). A very fast switch (23) is used to switch in the second source. In the example, a mechanical mercury wetted reed relay switch is used which allows a switching time of well below 1 ns. With this sort of rise time, this can give an effective square wave pulse (or at least the forward part thereof) at high power without actually generating the pulse electronically. It becomes possible to gain an effective reading after a sample time (and therefore after an effective pulse length from the prospective of the device) of a few ns, and possibly even as low as 1 ns or less. As with the previous example, this example exploits the point that all that functionally matters in accordance with the invention is the profile of the leading edge of the square wave and the effective pulse length created by the sample time.

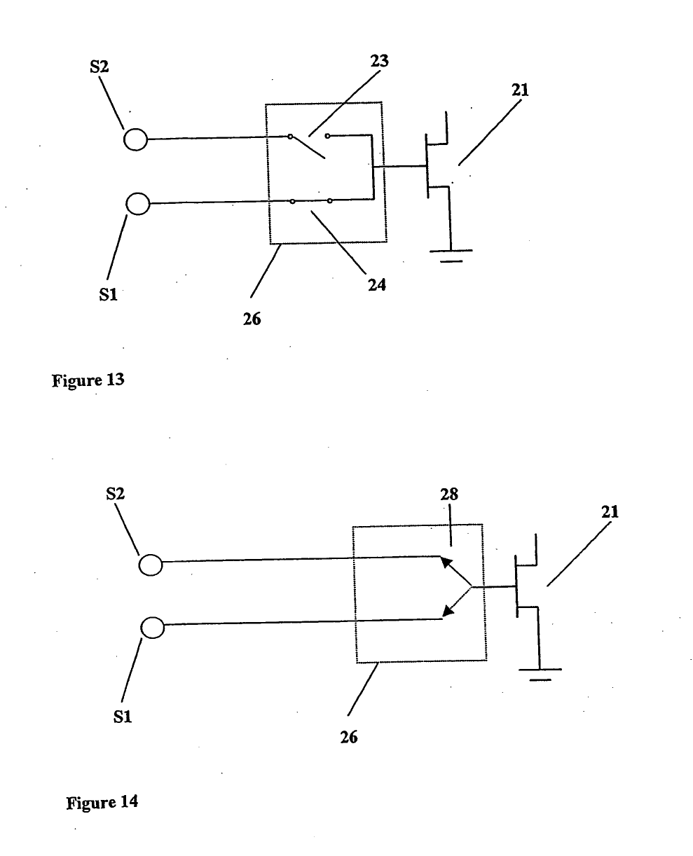

In the example a second switch (24) isolates the first source. It will be apparent that an effective square wave can be generated either by superimposition of S1 and S2 or by rapidly selectively switching between S1 and S2 dc signals of different amplitude. FIG. 14 shows an alternative switch (28) for this latter function. In all cases to avoid stray capacitances in cabling degrading effective rapid pulse rise, the distance to te DUT is kept as short as possible, and in the example the switching is included with suitable control electronics and sampling means (not shown) in a remote head (26) providing for direct connection to the DUT.

It is also useful to take measurement via a remote head, for example to minimise spurious results attributable to parallel capacitance from the capacitance of any connecting cable and series inductance from the inductance of any connecting cable. For some applications an instrument in accordance with the invention preferably provides a remote head for direct connection to the DUT which includes such measurement means. Depending on application this remote head for sensing may additionally embody the signal generation means, or at least the pulse generation means such as the switches, described above.

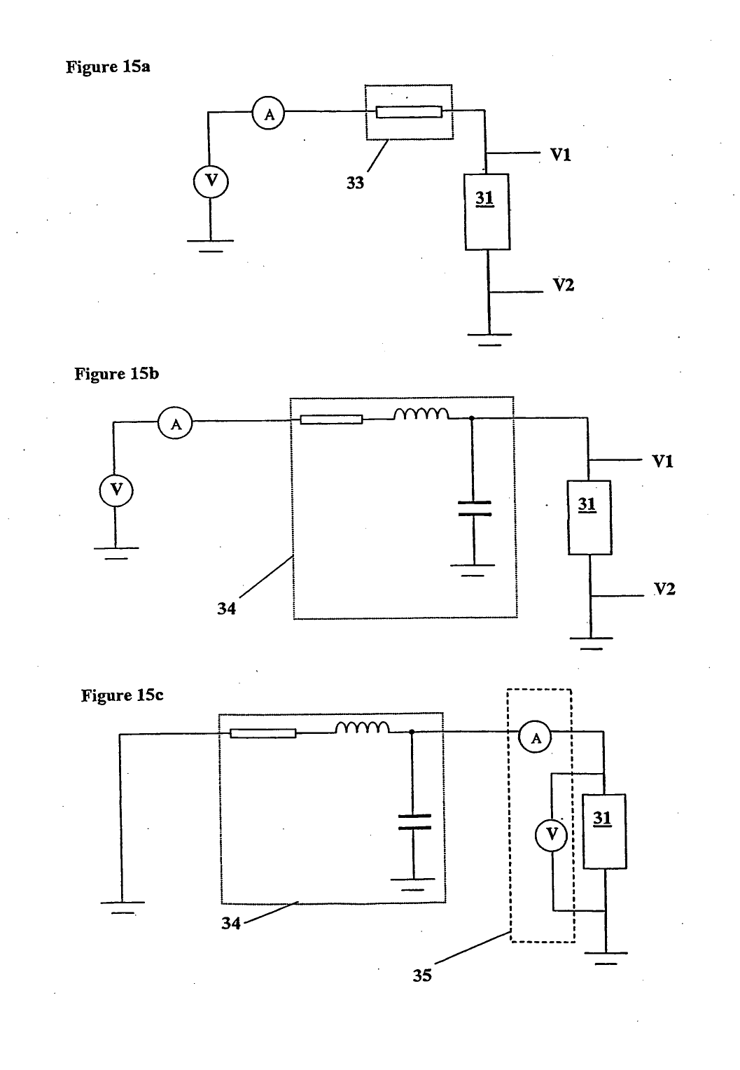

FIG. 15 illustrates the value of a remote head in such a case, the figure illustrating the bare principle of four-point probe measurements, and what becomes of it in a fast-pulse measurement.

At dc or very low frequency (FIG. 15a) the main problem is that parasitic resistance (represented by the box 33) in cables, connectors and contacts gives rise to a voltage drop that adds to the voltage drop across the device-under-test (31), producing an error if the device voltage is measured at the generator (i. e. instrument) end of the cables. The answer is to measure the voltage right at the device, thereby implying four terminals as close as can be to the DUT itself: two to deliver the current to the device, and two to measure the resultant potential across it (V1, V2). This is the basis of the conventional four point approach.

If the same four-point probe approach is tried in fast-pulse measurements, there is an added complication. Parasitic capacitances and inductances in the cable run (represented schematically by the box 34) become an issue. There is a problem in particular with current, in parallel with the current the DUT (31) passes, flowing in the cable capacitance. Such a current constitutes an error current because it is measured, along with the desired device current, by the ammeter A (FIG. 15b).

The answer to this problem, illustrated in FIG. 15c, is to move the ammeter to the DUT side of the cable, where the four-point probe principle has already placed the voltage sensing points. What the resultant configuration amounts to is a complete remote-sensing head (35) (and, as an aside, the means for generating the pulses themselves may be incorporated in the head also, particularly if these are the switching apparatus of FIGS. 13 to 14). A simpler alternative for early generation instruments is to retain both current and voltage sensing within the instrument itself and to develop some rules as to what cable and DUT mounting configurations are admissible as a function of pulse length.

1. An instrument for determination of the dc safe area of operation of a semiconductor device-under-test comprises a first dc biaser to apply an adjustable dc bias at a first channel of a device-under-test, and a means to apply a bias signal at a second channel of a device-under-test which means comprises a second dc biaser to apply a dc bias at a bias point within the safe operating limit, and a variable biaser subsequently to apply a variable stimulus comprising fast, superimposed rectangular bipolar pulses, and wherein the instrument further comprises means to measure the current response thereto so as to permit extrapolation of a detailed I-V response in the vicinity of the safe operating limit.

2. An instrument in accordance with claim 1 wherein the variable biaser generates pulses with progressively increasing amplitude.

3. An instrument in accordance with claim 1 wherein the variable biaser generates a pulsed wave form that is essentially critically damped so as to achieve a minimum rise time up to the point where the pulses become substantially flat.

4. An instrument in accordance with claim 1 wherein the variable biaser generates a pulsed wave form with a pulse length below about one μs.

5. An instrument in accordance with claim 4 wherein the variable biaser generates a pulsed wave form with a pulse length below about 100 ns.

6. An instrument in accordance with claim 1 wherein the means to apply the adjustable bias at the input comprises a high stability voltage source serially connected to the input via a resistor.

7. A measuring instrument in accordance with claim 6 wherein the high stability voltage source is further serially connected through a low pass filter.

8. A measuring instrument in accordance with claim 7 wherein the resistance is followed by a combination of series inductors and shunt capacitors to form the low pass filter.

9. A measuring instrument in accordance with claim 1, further comprising a remote head including at least the response measuring means, into which the device-under-test may be directly connected.

10. A measuring instrument in accordance with claim 1, further comprising a remote head including at least means to generate the superimposed fast, generally rectangular, synchronous bipolar pulses, into which the device-under-test may be directly connected.

11. A method for determination of the dc safe area of operation of a semiconductor device-under-test comprising the steps of:
applying a dc bias at a first channel such as the input of the device-under-test;
applying a dc bias at a second channel such as the output of the device-under-test at a bias point base level within the safe operating limit of the device-under-test;
applying a variable stimulus at the second channel comprising superimposed fast rectangular bipolar pulses;
rapidly measuring the current response thereto at both the channels;
extrapolating from the responses a detailed I-V response for the device in the vicinity of the safe operating limit.

12. A method in accordance with claim 11 wherein the variable bias is applied in the form of pulses with progressively increasing amplitude.

13. A method for determination of the dc safe area of operation of a semiconductor device-under-test comprising the repeated performance of the steps in accordance with claim 11 as an iterative succession.

14. A method in accordance with claim 13 comprising the steps of:
applying an initial dc bias at a point known to be well within the safe operating area of the device-under-test;
superimposing a pulsed bias and in particular a pulsed bias of progressively increased amplitude;
detecting incipient breakdown and removing the pulsed bias;
determining a second dc biasing point nearer to but safely below the breakdown point as identified hereinbefore;
repeating the process steps above until a sufficiently accurate characterisation of the breakdown point is obtained.
